(19) United States
(12) Patent Application Publication
(10) Pub. No.: US 2023/0198007 A1
(43) Pub. Date: Jun. 22, 2023

(54) METHOD FOR THE MANUFACTURE OF AN ENERGY STORAGE DEVICE UTILISING LITHIUM AND A WEB COMPRISING INORGANIC SOLID ELECTROLYTE

(71) Applicant: Pulsedeon Oy, Tampere (FI)

(72) Inventors: Jari LIIMATAINEN, Tampere (FI); Ville KEKKONEN, Tampere (FI)

(21) Appl. No.: 17/926,112

(22) PCT Filed: May 12, 2021
(86) PCT No.: PCT/FI2021/050355

§ 371 Date: Nov. 17, 2022

(30) Foreign Application Priority Data
May 17, 2020 (FI) 20207087

(51) Int. Cl. H01M 10/0562; H01M 10/0525; H01M 4/66; H01M 4/04; H01M 4/38

(52) U.S. Cl. CPC H01M 10/0562; H01M 10/0525; H01M 4/661; H01M 4/0404; H01M 4/382; H01M 4/0471; H01M 2004/028

(57) ABSTRACT

A method is for the manufacture of materials used in electrochemical energy storage devices. The manufacturing utilizes processing of the material layers by pressure and/or temperature, a porous, non-conducting substrate web (1A, 1B, 1C). An organic solid electrolyte (2A, 2B, 2C) is attached to and impregnated into the substrate web. The manufacturing processes a lithium-metal anode (11), and a cathode layer containing cathode-material particles together with polymer solid electrolyte and/or inorganic solid electrolyte and/or liquid electrolyte as well as with other necessary constituents.

### FIELD OF THE INVENTION

The invention is related to electrochemical energy storage devices utilising lithium such as batteries, to their structure, and to manufacturing of materials used in these devices. The invention is related especially to the manufacturing method of at least one lithium-comprising component of a lithium-ion battery, which method utilises various coating methods as well as methods of compaction and attaching of materials.

### BACKGROUND OF THE INVENTION

As the amount of mobile devices and electrically operated cars increases and the need for energy storage grows, the need for the development of energy storage technologies has increased. Li-ion batteries have been successful in very many applications, especially due to their good energy density and recharging possibilities compared, among others, to traditional Ni—Cd (Nickel-Cadmium) and Ni—Mn (Nickel-Manganese) batteries.

Today, the widely adapted lithium-ion battery technology is based on a positive electrode (cathode) made of transition metal oxide and on a carbon-based negative electrode (anode). Conduction pathway for the Li-ions between the positive and negative electrodes is the electrolyte which in the contemporary solutions mostly is liquid, but ways to use solid state electrolytes are being developed actively. Especially in the case of liquid electrolyte, a microporous polymer separator is used between the anode and cathode as an insulator which prevents the contact of the anode and cathode but allows the passage of ions through the separator membrane.

The energy density of Li-ion batteries is defined by the capability of the electrode materials to reversibly store lithium as well as by the amount of lithium available for ion exchange in the battery. When a battery is being operated, meaning energy is drawn from or stored in the battery, lithium ions move between the positive and negative electrodes. During operation, chemical and structural changes take place in the electrode materials which can affect the lithium storing capabilities of the materials or the amount of lithium.

In Li-ion batteries, it is possible to utilise lithium-metal anode which has the advantage of enabling high energy density, but its use is limited by the uncontrolled growth of so-called Li dendrites, i.e., formation of needle-like projections, which can cause short-circuiting of the battery cell because dendrites are able to penetrate the separator membrane and electrically connect the anode and the cathode. This is a major safety risk. Also, lithium is highly reactive, which is why special arrangements in its handling and usage are required in order to avoid the harmful effects of the reaction products.

As mentioned previously, the use of Li-metal anodes is partly limited by the risk of the growth of dendrites from the anode to the cathode, which can cause short-circuiting and damage of the battery, fire, or even an explosion. One way to prevent the growth of dendrites is to use solid electrolytes which can be either inorganic materials or polymers. Inorganic, mechanically strong, and defect-free materials are more effective than polymers in preventing the growth of dendrites from the anode to the cathode. Furthermore, the ionic conductivity of polymers at room temperature is not as good as that of the best inorganic solid electrolytes, such as LPS materials (e.g., Li₇P₃S₁₁, Li_{9.6}P₃S₁₂), and to improve the ionic conductivity, it might be necessary to warm up the batteries. On the other hand, the advantage of polymer solid electrolytes is their better flexibility which reduces the stresses generated within materials and at interfaces upon volume changes related to charge and discharge of batteries.

One challenge related to the use of inorganic solid electrolytes is the difficulty to manufacture a thin material layer which has good ionic conductivity, and which can prevent the contact between the anode and the cathode as well as the growth of lithium dendrites from the anode to the cathode. In the traditional Li-ion battery solutions based on utilisation of liquid electrolytes, contact between the anode and the cathode is prevented by a porous polymer separator membrane which has been impregnated with an ion-conducting liquid electrolyte. In addition, an inorganic porous coating can be applied on the surface of the polymer separator to improve thermomechanical durability of the separator and to block the growth of lithium-metal dendrites through the separator.

One option to manufacture a material layer composed of solid electrolyte is to use various thin-film deposition methods, such as chemical vapor deposition (CVD), physical vapor deposition (PVD), pulsed laser deposition (PLD), and atomic layer deposition (ALD). These methods can be applied for manufacturing ion-conducting material layers from many different inorganic materials, however, a problem related to these methods is their low productivity, which can limit their utilisation possibilities at least when manufacturing thick material layers. In addition, several of the methods have limited capabilities for controlling the crystallinity of material, meaning that reaching optimally good ionic conductivity becomes difficult for example in the case of lithium thiophosphates (LPS, LGPS) and oxides (e.g., LLZO=Li—La—ZrO). For many inorganic solid electrolytes, the ionic conductivity improves with increasing degree of crystallinity, and especially certain crystal structures have good ionic conductivity. Several thin-film deposition technologies also have the problem of causing high thermal load on the substrate, which thermal load can degrade the properties of heat-sensitive materials and the quality of contacts. For example, the melting point of lithium is approximately 180° C., and it is not possible to deposit coatings on lithium by using methods which have high process temperatures, methods such as certain CVD and ALD processes as well as commonly applied PVD process sputtering.

Layers of inorganic ion-conducting solid electrolyte can be manufactured also by sintering of material layers prepared from pre-compacted powders. Such a sheet-like structure can be applied to be a part of a battery-cell assembly as a separator layer between anode and cathode. The problem of this approach is that it is difficult to produce solid electrolyte as a thin sheet, which would be necessary for avoiding decreasing the energy density of the battery, as the solid electrolyte is not one of the active materials of the battery. A further problem is the difficulty to generate reliable bonding between the solid electrolyte produced this way and the active materials on the anode and the cathode. The bonding process can be combined with the sintering process, but many of the inorganic solid electrolytes require high sintering temperatures, often higher than 1000° C., which makes the bonding during sintering inapplicable in the case lithium metal or polymer materials are involved. Also, sintered structures often have defects, such as pores or weakly fused particles, after sintering process, which defects together with grain boundaries and particle boundaries form a pathway for the growth of lithium-metal dendrites through the solid-electrolyte layer.

Especially on the cathode side, one of the problems is how to guarantee the conduction of ions along the structures formed of solid electrolyte, particularly in the case of thick cathode layers. If the cathode layer is thick, the solid electrolyte does not necessarily form continuous conduction pathways through the whole structure.

On the other hand, among inorganic solid electrolytes, the materials have big differences in their stiffnesses, i.e., Young's moduli. For example, lithium thiophosphates, such as Li₇P₃S₁₁, have significantly lower Young's moduli than many oxides, such as LLZO. Lower Young's modulus reduces the generation of stresses due to volume changes in different components during charge and discharge of a battery, which is relevant especially in the case of large and thick Li-ion battery solutions, such as those used in batteries of electric vehicles.

One way to produce reliable thin structures of inorganic solid electrolytes is to manufacture them using rolling or other forming processes, such as uniaxial pressing. However, many solid electrolytes have poor formability, which means that they cannot be manufactured into continuous thin webs which have good handleability. For example, oxide materials, such as LLZO, or oxynitrides, such as UPON, are not suitable for manufacturing into thin webs because of the fragility and poor formability of these materials.

Certain inorganic solid electrolytes, such as lithium thiophosphates (LPS and LGPS), are formable, however also in the case of these materials, the problem is their mechanical reliability and handleability especially as thin webs, which thinness would be advantageous for the operation and energy density of Li-ion batteries as well as for the performance of the batteries. The thicker the solid-electrolyte layer, the lower the energy density of the batteries, because the solid electrolyte does not belong to the active, lithium-storing material layers. Furthermore, as the thickness of the solid-electrolyte layer increases, the need for good ionic conductivity is emphasized because the total resistance is wanted to be kept at minimum.

As a summary one could state, that currently there is no availability of a manufacturing process and a solution which would combine the use of lithium-metal anodes, reliable adhesion of lithium metal to current collectors, manufacturing of thin structure of solid electrolyte as a part of Li-ion battery manufacturing, as well as a reliable material and structural solution for preventing the growth of lithium-metal dendrites from the anode to the cathode.

### SUMMARY OF THE INVENTION

The present invention discloses a method for the manufacture of an energy-storage device based on lithium-metal anode, which device comprises a thin electrolyte web made of inorganic solid electrolyte and suitable for mass production, and in which device inorganic or polymer solid electrolyte or liquid electrolyte can be utilised in the cathode layer.

The topic of the present invention has been previously discussed in the following patent applications which represent the prior art:
US2018/0375148 A1 “Ionically-conductive reinforced glass ceramic separators/solid electrolytes”. The patent application discloses a fiber-material reinforced solid electrolyte which is applicable for use in a cell with an alkali-metal anode.
WO2019/034563 A1 “Composite reinforced solid electrolyte to prevent protrusions”. The patent application discloses a solid electrolyte mixed with fibers, particles, or plates, where the constituents of the mix reduce and prevent fractures in the material layer.

In the method of the present invention, an electrolyte web is manufactured by utilising a porous, essentially non-conducting substrate to which ion-conducting inorganic solid-electrolyte material is combined. The inorganic solid electrolyte needs to form pathways through the porous substrate web so that the Li-ion flow necessary for the operation of a battery would be possible. The structure does not need to be completely dense in order to guarantee sufficient ionic conductivity, but, for example, for preventing the growth of lithium-metal dendrites through the electrolyte web, as good as possible density and integrity of the electrolyte web would be advantageous features.

First, inorganic solid electrolyte is spread onto and impregnated into the non-conducting porous substrate web. The intention is to get the inorganic solid electrolyte through the substrate web by using a technology as straightforward as possible, however, taking into account the productivity requirements especially in cases where the electrolyte web is thick, meaning thicknesses greater than 25 micrometers. The solid electrolyte can be produced inside and/or on the surface of the porous, non-conducting web by using one method or a combination of several methods.

Thin-film deposition methods, such as ALD, PVD, CVD, and PLD, are applicable especially in cases where the non-conducting substrate web is sufficiently porous and open, such that the material produced by the deposition methods forms a continuous structure as contiguous as possible through the substrate web thus enabling conduction of ions and preventing the growth of dendrites from the anode to the cathode. The methods mentioned above do not necessarily have the productivity sufficient for all cases, but it is recommended to use the methods when the desired thickness of the electrolyte web is not great. Furthermore, not all of the methods enable the coating material to penetrate into all areas within the structure of the porous substrate web if the methods are not conformal enough but so-called line-of-sight methods, i.e., able to access only those areas which have straight unobstructed view to the source of the coating material. Generally speaking, ALD and CVD methods are conformal which means that they can produce material inside a porous structure. PVD and PLD methods are intrinsically line-of-sight methods meaning that the produced material flow propagating principally along direct paths can access only those areas on the substrate which areas have direct view to the point of origin of the coating material. Thus, these methods are not necessarily able to produce coating on those areas of structures of a porous substrate which areas are behind other structures of the substrate when viewed from the point of origin of the coating material.

The aforementioned thin-film deposition methods have the advantage that they can, in principle, be utilised for producing coatings of various materials. On the other hand, they have the limitation that they tend to produce amorphous structures which do not have sufficiently good ionic conductivity in the case of all inorganic solid electrolytes. Then, the material layers can be subjected to, for example, post-production heat treatment for converting the amorphous structure into partially crystalline form but, in this case, one needs to take into account how the non-conducting, porous material of the substrate and its structures can withstand the temperatures used in the post-production thermal treatment.

On the other hand, the inorganic solid electrolyte can also be spread as a powder or as a web onto the surface of the porous, non-conducting substrate web and, after this step, push the inorganic solid electrolyte into and through the porous substrate web by means of pressure and/or temperature. This process step is difficult to be executed on such inorganic solid electrolytes which have high hardness and poor deformation capability and formability, such as oxides. Then, lithium thiophosphates, such as LPS and LGPS, have, especially at elevated temperatures, better deformation capability and compressibility. When impregnating porous substrate webs from one side or both sides with these materials, it is possible to generate the desired structure and penetration of the inorganic solid electrolyte into the porous substrate web.

The inorganic solid electrolyte can be produced on the surface and partly on the inside of the porous, non-conducting substrate web also by spraying or printing. Also with these methods, it is challenging to impregnate the inorganic solid electrolyte on the inside of the porous substrate web, and, in order to enable as-good-as-possible penetration, forming and/or temperature need to be used.

Whatever the manufacturing means for producing inorganic solid electrolyte on the surface or on the inside of the porous, non-conducting substrate web, thermal treatment may be necessary, as mentioned previously, also for controlling crystallinity of the structure and improving ionic conductivity. This can be performed as a separate process step or, for example, during rolling or pressing.

The handling environment needs to be considered when performing the impregnation with inorganic solid electrolyte. Especially in the case of lithium thiophosphates, the processing needs to take place in a controlled gas atmosphere, where, inter alia, moisture content should preferably be below 1-2 ppm.

On the surfaces of the electrolyte web comprising inorganic solid electrolyte, also other functional materials of a Li-ion battery should be produced. Lithium metal deposition should be carried out using a method which guarantees good adherence to the substrate, enables adjusting the thickness of the lithium-metal layer, and enables the manufacturing of very thin layers as well. In addition, the deposition should be carried out in an environment where lithium is not exposed to moisture, oxygen, or other contaminants of the environment. For example, pulsed laser deposition (PLD) technology is highly applicable for this purpose. A further advantage of PLD is that the thermal load caused on the substrate is minor, which means that it can be used for producing coatings also on heat-sensitive materials. It is also possible to first produce only a thin layer of lithium by PLD method, which guarantees good adhesion and minimizes risks for damages of the substrate, and, as a following step, perform continuation of lithium-metal deposition by a higher-productivity method, such as thermal evaporation, on top of the lithium produced by PLD technology.

It could be necessary to produce a protective layer between the lithium-metal layer and the electrolyte web. This is necessary especially in the case that the materials would react with each other without the use of protective layer thus causing decay in performance of a battery. For example, a reaction layer can be formed at the interface between lithium thiophosphate and lithium, which layer can hinder or prevent conduction of ions and thus also the operation of a battery. A suitable interlayer can be, for example, an inorganic, sufficiently ion-conducting material. The deposition of the inorganic, sufficiently ion-conducting material layer can be performed using one of several alternative methods, such as pulsed laser deposition (PLD), chemical vapor deposition (CVD) or physical vapor deposition (PVD) or atomic layer deposition (ALD). As in the case of lithium metal, the method should be selected such that it is applicable to the materials used and that it does not cause damage to the substrate due to, for example, too high thermal load or kinetic energy. In the case of the inorganic material, this has especially high importance, because in the approach of the present invention, the substrate can be low-melting-point lithium metal or porous, non-conducting material, such as, for example, cellulose or other natural material, polymer, or glass fiber.

The cathode material should be selected based on the overall design of the Li-ion battery, such that both stability with and good adherence to the electrolyte web comprising inorganic solid electrolyte is guaranteed. The cathode can be based on the use of liquid electrolyte, polymer electrolyte, or inorganic solid electrolyte, and the manufacturing of the cathode-material layer as well as the attachment of the cathode-material layer on the electrolyte web comprising inorganic solid electrolyte need to be selected accordingly.

The inventive idea of the invention also comprises the final product manufactured using the method, i.e., a Li-ion battery comprising the relevant material layers, such that at least one layer containing lithium metal or lithium compound is manufactured by laser ablation deposition.

### SHORT DESCRIPTION OF THE DRAWINGS

FIG. 1 illustrates a possible process for producing a coating of inorganic solid electrolyte on a porous, non-conducting substrate web and at least partially impregnating the porous, non-conducting substrate web with the inorganic solid electrolyte by using PLD method.

FIG. 2 illustrates a certain possible process for producing a coating of inorganic solid electrolyte on a porous, non-conducting substrate web and at least partially impregnating the porous, non-conducting substrate web with the inorganic solid electrolyte by mechanically spreading the inorganic solid electrolyte on the surface of the porous substrate web.

FIG. 3 illustrates the use of calendering for promoting the penetration and densification of an inorganic solid electrolyte inside a porous, non-conducting substrate web.

FIG. 4 illustrates the manufacturing of the subsequent coating layers on the surface of a substrate web which comprises solid electrolyte and which has been post-processed by means of pressure and/or temperature, such that at least one coating layer is produced, shown here as an example in the case of manufacturing a lithium-metal layer by using PLD method.

### DETAILED DESCRIPTION OF THE INVENTION

In the method of the invention, a component suitable for energy storage is manufactured, structure of which component comprises at least an electrolyte web which is composed of inorganic solid electrolyte and porous, non-conducting substrate web, a lithium-metal layer on the anode side, as well as possible protective layers or interlayers which improve the reliability and performance of a battery. In addition, the structure of this solution comprises a cathode where the cathode-material particles are together with liquid electrolyte, polymer electrolyte, and/or inorganic solid electrolyte.

In the method of the invention, it is essential to use electrolyte web which comprises inorganic solid electrolyte as well as a porous, non-conducting substrate web. The purpose of a porous, non-conducting substrate web is to form a skeleton which supports inorganic solid electrolyte, such that the electrolyte web and the inorganic solid electrolyte within withstand the subsequent steps of Li-ion battery manufacturing as well as the stresses during the operation of the battery. The porous substrate web needs to be electrically insulating, like for example an organic material, such as cellulose or non-conducting polymer. Substrate web's thickness and internal structure, such as porosity and pore distribution, need to be selected such that they are suitable with the chosen manufacturing and impregnation methods of the inorganic solid electrolyte. A fundamental feature is to enable the penetration of the inorganic solid electrolyte through the whole porous, non-conducting substrate web. On the other hand, the porous, non-conducting substrate web should be strong enough to enable handling of the web without risk for damages after the deposition of and impregnation with the inorganic solid electrolyte. The porous substrate web should comprise at least 5 percent by volume of the total volume of the final electrolyte web in order to achieve sufficient strength of the structure. The final electrolyte web could thus be comprised of at most 95 percent by volume of inorganic solid electrolyte. On the other hand, the proportion of the porous substrate web should not be too great after the impregnation with the inorganic solid electrolyte, such that one can guarantee sufficient ionic conductivity. In practice, this means that the proportion of the porous substrate web in the final electrolyte web cannot be higher than 60 percent by volume. The final electrolyte web should be as thin as possible, such that the energy density of the battery could be as high as possible and the performance of the battery as good as possible. On the other hand, the thickness should be sufficient for the mechanical properties of the web and in order to prevent the growth of lithium dendrites from the anode to the cathode. The thickness needs to be less than 200 micrometers, preferably less than 100 micrometers, and most preferably less than 50 micrometers.

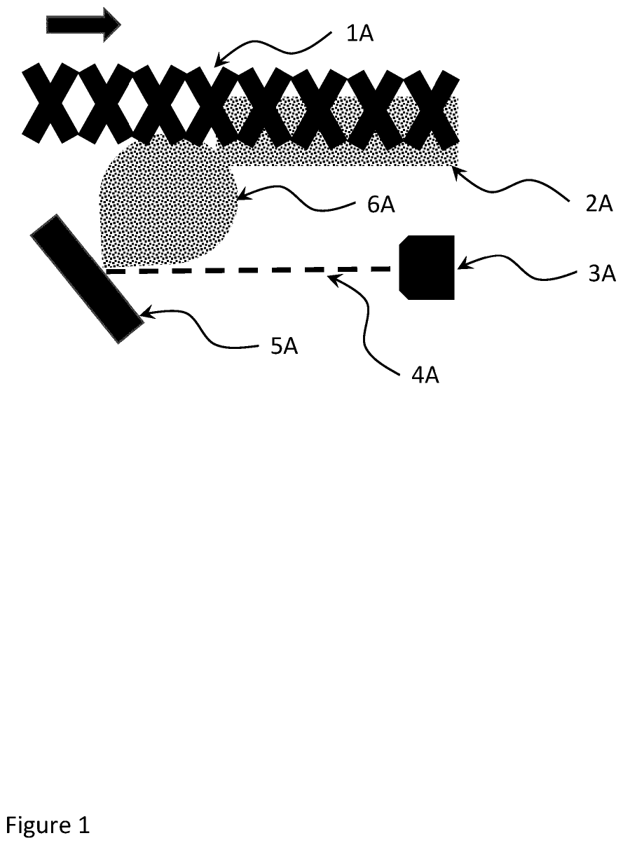

FIG. 1 represents a simplified schematic of a coating process, in which the surface and the inside of a non-conducting, porous substrate web 1A is coated and impregnated with inorganic solid electrolyte 2A. In this example shown in FIG. 1, the method used is pulsed laser deposition (PLD) in which laser pulses 4A generated in the laser source 3A are directed to a target 5A made of inorganic solid electrolyte (or constituents of such), thus forming a material flow 6A which upon impinging and attaching to the substrate web 1A forms a coating and a layer of inorganic solid electrolyte 2A impregnated partly inside the substrate web 1A. In the figure, the substrate web 1A moves from left to right to the direction indicated by the arrow through the material flow 6A, whereupon a desired amount of inorganic solid electrolyte 2A can be produced on a desired surface area.

The heat resistance of a porous, non-conducting substrate web should be sufficient such that it enables both the coating and the impregnation with inorganic solid electrolyte as well as the possible post-production thermal treatment. For example, in the case of many polymer webs the applicable maximum temperatures are 130-200° C. depending on the polymer, whereas in the case of, for example, organic fibers, such as cellulose, temperatures as high as 240-260° C. can be applied at least for short periods of time.

To increase the heat resistance and chemical stability of a porous, non-conducting substrate web, the web can be coated with a layer improving heat resistance and chemical stability, such as a thin aluminium oxide coating, before coating and impregnating with inorganic solid electrolyte. The thickness of this coating depends on the desirable properties, however, being at most 1 micrometer and preferably less than 100 nanometers or even less than 20 nanometers. The deposition can be performed, for example, by conformal methods, such as ALD and CVD methods, taking into account the heat resistance of the porous, non-conducting material with respect to the process temperature required by the method.

The best way to coat and partly impregnate a porous substrate web with inorganic solid electrolyte is to use a conformal method allowing access to all cavities of a porous material, such as CVD and ALD methods, if the methods in question are applicable to the utilised inorganic solid electrolyte materials and if the porous, non-conducting substrate web can withstand the temperatures of the deposition processes utilised. So called line-of-sight methods, such as PVD and PLD methods, which have worse ability to penetrate into porous materials, are alternative approaches for depositing materials applicable to the method, but they typically require post-production treatment by means of pressure and/or temperature in order to achieve sufficient penetration into the porous, non-conductive substrate web. The advantage of PLD method is small thermal load generated by the deposition process. In other PVD methods, such as sputtering, the thermal load is typically greater, which might prevent the use of these methods in the case of materials with low heat resistance.

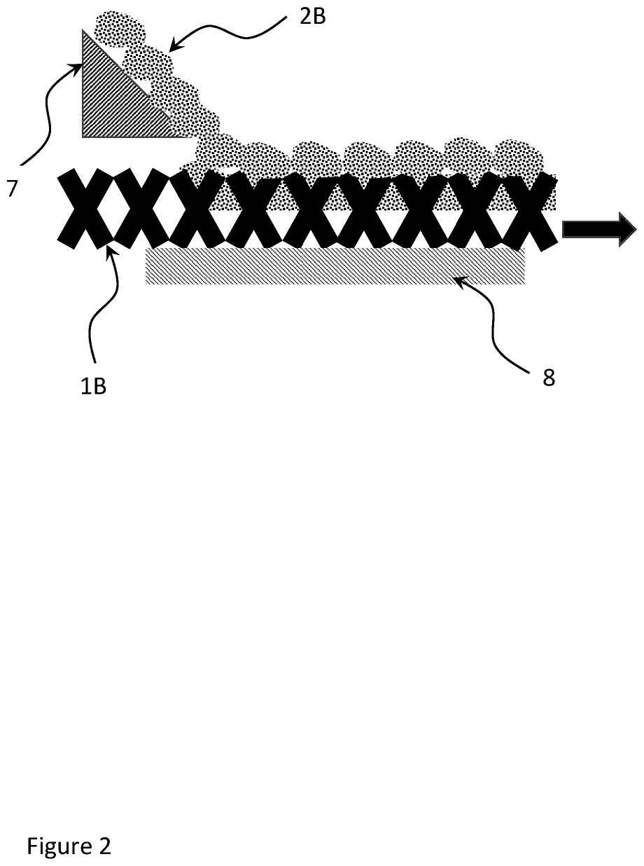

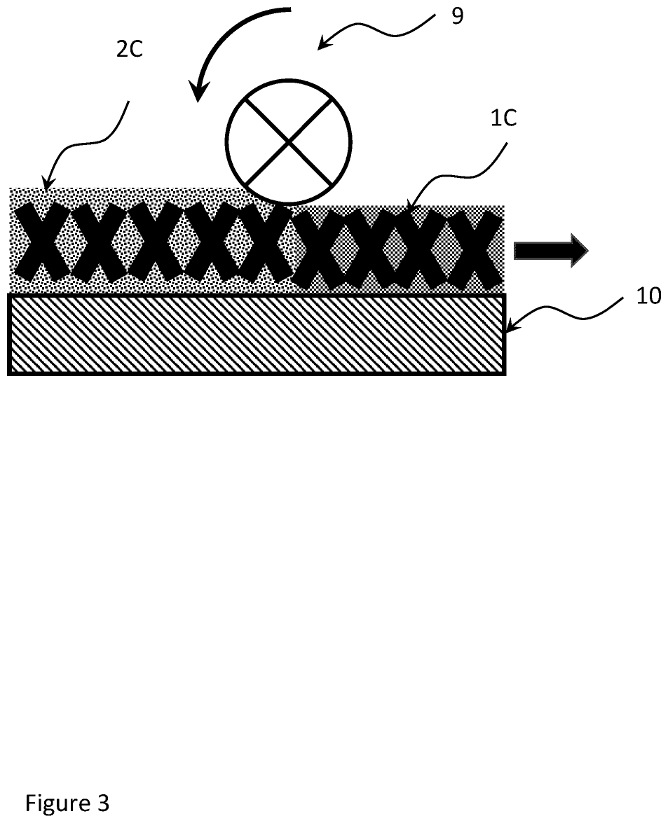

FIG. 2 represents an alternative way to spread inorganic solid electrolyte 2B as particles having suitable size on the surface and partly inside of a porous non-conducting substrate web 1B by utilising suitable spreading tool 7. It is preferable to select the particle size of the inorganic solid electrolyte 2B such that, if possible, it penetrates into the porous non-conducting substrate web 1B. During the spreading process it could be advantageous to use a supporting surface 8 on the other side to prevent the particles from falling away through the substrate web 1B. In the figure, the substrate web 1B moves from left to right to the direction indicated by the arrow, such that a desired amount of inorganic solid electrolyte 2B can be dosed on a desired surface area. This method according to FIG. 2 requires a mechanical or thermal treatment after spreading the inorganic solid electrolyte in order to promote the penetration and densification of the inorganic solid electrolyte 2B according to the example presented in FIG. 3.

FIG. 3 represents a schematic of a solution, in which a solid electrolyte 2C is aided to penetrate into and is densified inside and on the surface of a porous, non-conducting substrate web 1C by means of a calender roller 9, for example, on a special working table 10. In the figure, the calender roller 9 rotates counter-clockwise to the direction indicated by the turn arrow, and the substrate web 1C and the solid electrolyte 2C attached to it move from left to right to the direction indicated by the arrow. Also other means for applying forming or pressure can be used, such as, for example, pressing by plates or use of two opposing rollers. The treatment can be performed by using temperature, for example, by utilising hot rollers.

The use of lithium thiophosphates, such as LPS and LGPS, as inorganic solid electrolytes to be impregnated into porous, non-conducting substrate webs has the advantages of their relatively good ionic conductivity even as amorphous structures as well as the possibility for post-production treatment at relatively low temperatures. In post-production treatment at temperatures 180-280° C., one can promote the penetration of lithium thiophosphates, such as LPS and LGPS, into the porous, non-conducting substrate web by means of cooperative action of pressure and temperature, and, at the same time, transform the structures of these materials from amorphous to at least partially crystalline and thus having better ionic conductivity.

On the anode side of a Li-ion battery, the lithium-metal deposition should be performed by a method which enables good adhesion, ability to control layer thickness, as well as minimizes thermal and mechanical damages on the electrolyte web comprising inorganic solid electrolyte, which web functions as a substrate. In addition, one needs to be able to prevent the reaction of lithium metal with the impurities of the environment, such as oxygen, nitrogen, carbon dioxide, and moisture, during and after the deposition process. PLD method is particularly applicable for the manufacture of the lithium-metal layer and it fulfils many of the aforementioned requirements. On the other hand, if the ambition is to manufacture a thick lithium-metal layer, an option is to first produce a thin lithium-metal layer by PLD method, after which the rest of the lithium-metal layer is produced with another, higher-productivity method, such as thermal evaporation. This way, in the case of, for example, thermal evaporation, the limitations related to achieving sufficient adhesion and problems caused by too high thermal load can be avoided. Considering the capacity of the cell of a Li-ion battery, a sufficient thickness of the lithium-metal layer is typically less than 50 micrometers. The amount of lithium needs to be matched with the capacity of the cathode and in such a way that the amount consumed by possible irreversible reactions is taken into account such that the amount of lithium is not causing a bottleneck for the total capacity of the cell.

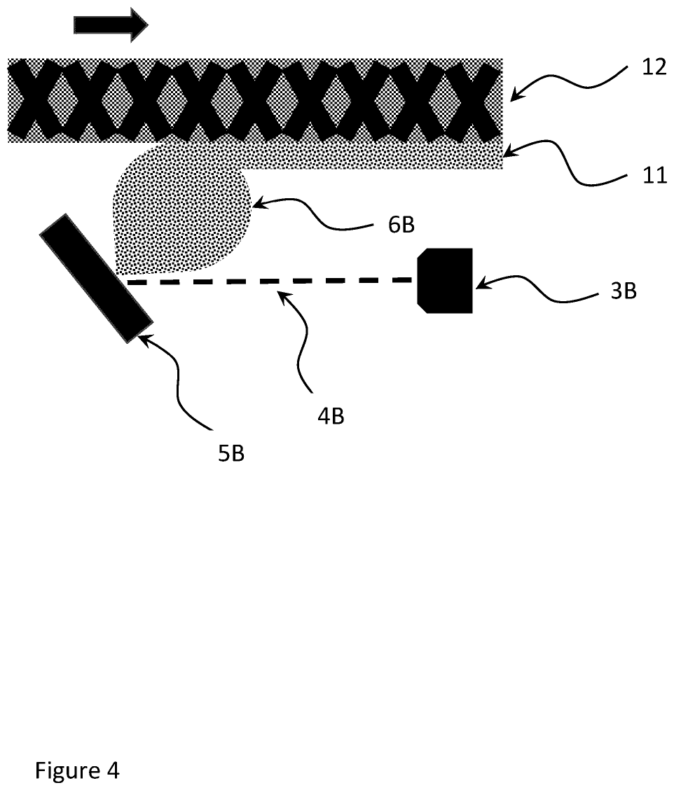

FIG. 4 represents a method for depositing a lithium-metal layer 11 on the surface of an electrolyte web 12 comprising inorganic solid electrolyte. In the example of FIG. 4, the deposition method utilised is pulsed laser deposition PLD, in which laser pulses 4B generated in the laser source 3B are directed to a lithium-metal target 5B, thereby removing material and forming a material flow 6B which upon impinging and attaching to the surface of the electrolyte web 12 forms a coating layer 11 which is essentially lithium metal. In the figure, the electrolyte web 12 moves from left to right to the direction indicated by the arrow, such that a lithium-metal layer of a desired thickness can be deposited on a desired surface area.

Attaching a lithium-metal layer directly to materials comprising inorganic solid electrolytes is not advantageous in all cases, because of the reactions taking place at the interfaces during manufacture and/or operation. For example, the interface between lithium metal and solid electrolyte LPS is not stable in all circumstances. In order to reduce the detrimental interface reactions, one can manufacture an inorganic material layer between a lithium-metal layer and an inorganic solid electrolyte, which inorganic layer does not generate detrimental reactions with neither of the interface materials, i.e., neither lithium metal nor LPS. Deposition of the interlayer on the surface of the inorganic solid electrolyte can be performed by various thin-film deposition methods, such as ALD, PLD, CVD, and PVD, taking into account the same limitations as in the case of lithium-metal deposition, i.e., one needs to be able to generate sufficient adhesion and density but, at the same time, keeping the thermal load on the substrate as low as possible. As in the case of lithium metal, PLD as well as ALD method are both well applicable for the manufacture of this interlayer material. The inorganic interlayer material should have high enough ionic conductivity, so that it does not pose limitations to battery operation during charge and discharge phases. In the case of LPS material and lithium metal, for example LLZO material is applicable between the materials. Interlayer thickness sufficient for reaching the desired effect can in certain cases be less than 10 nm. Depending on the surface quality of the substrate to be coated and properties of the interlayer material, the required layer thickness can also be greater, however, less than 10 micrometers and preferably less than 5 micrometers.

On the other side of the electrolyte web comprising inorganic solid electrolyte, one needs to attach a cathode, manufacture of which can be performed with different methods. A cathode is composed of active cathode-material particles as well as of liquid electrolytes and/or solid polymer electrolytes and/or inorganic solid electrolytes and, in addition, of other potentially necessary constituents, such as conductive carbon improving electron conduction. If inorganic solid electrolyte is used as the electrolyte, it is possible to prepare a mixture of cathode-material particles, particles composed of solid-electrolyte material, and other necessary constituents, for example, by mechanical mixing in a ball mill, after which the mixture is spread, for example, on a metal current collector. After this step, attachment to electrolyte web comprising inorganic solid electrolyte can be performed by means of pressure and/or temperature. It would be advantageous in this case, that the solid electrolytes in both the cathode layer and the electrolyte web would have compositions as similar as possible and would be attachable to each other by means of temperature and/or pressure. The cathode mixture can also be compacted and attached to a metal current collector by means of pressure and/or temperature before attaching to an electrolyte web comprising inorganic solid electrolyte.

Instead of or in addition to the inorganic solid electrolyte, also polymer electrolyte or liquid electrolyte can be used in the cathode layer, impregnation of which electrolytes between cathode-material particles is easier than in the case of inorganic solid electrolyte. On the other hand, the ionic conductivity of polymer solid electrolytes at room temperature is worse than that of the best inorganic solid electrolytes, such as LPS or LGPS. Liquid electrolytes have good ionic conductivity, but their problem is, among other things, greater risk of catching fire or exploding, for example, in the exceptional circumstances caused by a short circuit.

It might be necessary to produce a protective interlayer with sufficient ionic conductivity also between cathode and electrolyte web comprising inorganic solid electrolyte. A suitable interlayer is a thin, inorganic material layer, which has thickness of at most 5 micrometers, but the desired functionality of the interlayer can be achieved also with less than 100 nanometers, less than 20 nanometers, or even less than 10 nanometers thick layer. As in the case of the interlayer on the anode side, the manufacturing is characterised by the same limitations and criteria which are good adhesion, chemical stability, and sufficiently good conduction of ions. Furthermore, the deposition method should not cause thermal or mechanical damage on the electrolyte web comprising inorganic solid electrolyte functioning as a deposition substrate. Suitable methods are, inter alia, PLD and ALD.

In the following, features of the invention are further compiled in a list-type form in the way of a summary.

The invention relates to a method for manufacturing a component applicable to energy storage. The component is composed of an electrolyte web comprising inorganic solid electrolytes, a lithium-metal anode, and a cathode which utilises liquid electrolytes, polymer electrolytes, and/or solid electrolytes, as well as of inorganic protective layers. The method comprises the following steps:
In the case of the electrolyte web comprising inorganic solid electrolytes:
   Inside and on the surface of a non-conducting, porous substrate web, as contiguous as possible ion-conducting structure is produced of inorganic solid electrolyte.
   The inorganic solid electrolyte is produced either by means of a coating method, such as ALD, PLD, PVD, or CVD, spraying, printing, spreading, or by means of some other method on the surface and inside of the non-conducting, porous web.
   If necessary, a mechanical and/or thermal treatment is performed on the produced structure in order to guarantee impregnation with and densification of the inorganic solid electrolyte as well as to control the microstructure, such as crystallinity.
In the case of the anode:
   On the surface of the electrolyte web comprising inorganic solid electrolytes, a lithium-metal layer is produced by one or several methods, thickness of which layer can be matched based on the amount of lithium taking part in the ion exchange and stored by the other components of a battery.
   The best alternative for producing the lithium-metal layer is pulsed laser deposition (PLD) because of adhesion and low thermal load, but, in addition to PLD, one could use also some other method, such as thermal evaporation.
   Before manufacturing the lithium-metal layer, if necessary, an inorganic protective material layer can be produced on the electrolyte web comprising inorganic solid electrolytes in order to prevent detrimental interface reactions. For manufacturing this protective inorganic material layer, a suitable deposition method, such as PLD, ALD, PVD, or CVD, can be applied, however, taking into account the thermal resistance of the substrate in the case of ALD, PVD, and CVD methods.
In the case of the cathode:
   A mixture of cathode-material particles and polymer electrolyte and/or inorganic solid electrolyte and/or liquid electrolytes, as well as of other necessary materials is prepared.
   The aforementioned mixture is attached to the electrolyte web comprising inorganic solid electrolyte by using different methods by utilising pressure and/or temperature.
   Especially in the case that inorganic solid electrolyte is used, the attachment process should be enhanced by means of pressure and/or temperature.
   If necessary, between the cathode-material layer and the electrolyte web comprising inorganic solid electrolyte, a protective layer of inorganic, sufficiently ion-conducting material should be produced by using a suitable method, such as PLD, CVD, ALD, or PVD.

In an embodiment of the invention, a Li-ion battery is further assembled in the method by using components which comprise an electrolyte web, lithium-metal layer on the anode side, and cathode layer on the cathode side. The electrolyte web has a substrate web made of cellulose as a skeleton and the electrolyte web comprises 85 volume percent of solid electrolyte LPS. The electrolyte web has a thickness of 40 micrometers, and a 1 micrometer thick coating of LLZO on the surface of the electrolyte web and, further 5 micrometers thick lithium-metal layer on the LLZO have been manufactured by pulsed laser deposition PLD. On the cathode side, a mixture of cathode particles NMC622 and polymer solid electrolyte has been produced as a layer of 80 micrometers in thickness, which layer has been attached to the electrolyte web comprising inorganic solid electrolyte by rolling at temperature 180° C.

In an embodiment of the invention, a mixture of solid electrolyte LPS and cathode particles NMC622 is used on the cathode side, which mixture is attached by hot calendering as a 50 micrometers thick layer to a 30 micrometers thick electrolyte web comprising solid electrolyte LPS, which electrolyte web has a cellulose web as a skeleton.

In an embodiment of the invention, a 40 micrometers thick electrolyte web comprising inorganic solid electrolyte LGPS has a porous cellulose web as a skeleton.

On the surface of the electrolyte web, a 10 nm thick layer of LLZO is deposited by ALD technology, on top of which layer, 5 micrometers thick lithium-metal layer is deposited by PLD technology.

In an embodiment of the invention, the cathode material is manufactured as a mixture of solid electrolyte LPS and cathode particles NMC622, such that the proportion of LPS in the mixture is 20 volume percent. After mixing, the material is spread on the surface of an electrolyte web comprising solid electrolyte LPS and hot calendered at temperature 240° C., which provides adhesion, densification, as well as partial crystallization of the LPS material in the cathode layer.

In an embodiment of the invention, cathode-material particles with an average size of 5 micrometers are coated with an approximately 5 nanometers thick Al₂O₃ coating by ALD method, and these coated cathode particles are impregnated into and combined with a polymer solid electrolyte, which is attached to an electrolyte web comprising 40 volume percents of solid electrolyte LPS, on the anode side of which electrolyte web PLD method is utilised to produce a 1 micrometer thick LiPON layer, a 5 micrometers thick lithium-metal layer, and, finally, a 5 micrometers thick copper current collector.

In an embodiment of the invention, a porous, non-conducting substrate web is coated with an approximately 4 nm thick Al₂O₃ coating by ALD technology, after which spreading of powdery solid electrolyte LPS on top of the coated substrate web is first performed, followed by hot calendering for impregnating the LPS inside the web, such that the proportion of LPS in the final electrolyte web is 85 volume percents.

In an embodiment of the invention, an electrolyte web comprising 80 volume percents of LPS is manufactured by using a porous cellulose web as a substrate web, on the anode side of which electrolyte web a 2 micrometers thick LLZO layer, further, a 5 micrometers thick lithium-metal layer, and, finally, a 2 micrometers thick copper layer are deposited. In addition, a cathode component is manufactured by attaching a mixture of NMC622 cathode particles and polymer solid electrolyte to an aluminum current collector, which mixture is solidified and attached at the same time on the cathode-side surface of the electrolyte web comprising inorganic solid electrolyte.

The method according to the invention has the following advantages:
i. It is possible to manufacture inorganic, well ion-conducting electrolyte webs which are mechanically durable and well handleable due to structural reinforcement generated by the porous substrate web
ii. It is possible to manufacture thin, controlled-thickness electrolyte webs comprising inorganic solid electrolytes which separate the anode and cathode layers and which can be used as substrates and supporting structures in the manufacture of other material layers of a Li-ion battery
iii. It is possible to apply Li-ion-battery solutions based on lithium-metal anodes without the risk of growth of lithium-metal dendrites from the anode to the cathode due to the use of an electrolyte web comprising inorganic solid electrolyte between the anode and the cathode, which electrolyte web is able to effectively prevent the growth of dendrites
iv. It is possible to prevent the activation of detrimental interface reactions at the interfaces of the functional material layers by utilising protective layers manufactured by various thin-film deposition technologies
v. It is possible to flexibly utilise various cathode material particles and electrolyte solutions in the manufacture of the cathode
vi. It is possible, if necessary, to avoid the use of liquid electrolyte and thus reduce fires and explosions of batteries in the case of damages
vii. It is possible to achieve a significantly higher energy density of Li-ion batteries by using thin electrolyte webs and lithium-metal anodes
viii. It is possible to manufacture batteries with both a considerably higher gravimetric energy density and a considerably higher volumetric energy density when compared to the conventional material solutions
ix. It is possible to manufacture batteries based on bipolar solutions

In the invention, it is possible to combine individual features of the invention mentioned above and in the dependent claims into new combinations, in which two or several individual features may have been included in the same embodiment.

The present invention is not limited only to the examples shown, but many variations are possible within the scope of protection defined by the enclosed claims.

1. A method for the manufacture of a lithium-ion battery comprising lithium and inorganic solid electrolyte, the method comprising:
a method for the manufacture of an electrolyte web comprising 40-95 volume percent of inorganic solid electrolyte,
a method for the manufacture of a lithium-metal layer,
a method for the manufacture of a cathode, such that cathode-material particles with a liquid electrolyte and/or a polymer electrolyte and/or an inorganic solid electrolyte, as well as with potential additives, together form a functional layer of the cathode on the surface of a metal current collector,
the inorganic solid electrolyte is attached to and impregnated into a porous, non-conducting substrate web,
the web is processed by pressure and/or temperature so that the inorganic solid electrolyte impregnates into pores of the substrate web and densifies to form ion-conducting pathways across the substrate web,
a lithium-metal layer is deposited on the anode side of the electrolyte web,
a cathode layer comprising cathode-material particles and either liquid electrolytes, polymer electrolytes, or inorganic solid electrolytes, and of other necessary constituents, is attached on the cathode side of the electrolyte web,
final mechanical and thermal treatments are performed as well as connections and depositions required for the current collector.

2. Method according to claim 1, wherein the lithium layer produced on the anode side is at most 50 micrometers thick.

3. Method according to claim 1, wherein in the manufacture of the lithium-metal layer, pulsed laser deposition technology is used at least in part.

4. Method according to claim 1, wherein before deposition of the lithium-metal layer (11), an inorganic material layer with thickness of at most 10 micrometers is deposited on the surface of the electrolyte web (12) comprising inorganic solid electrolyte.

5. Method according to claim 4, wherein the inorganic coating with thickness of at most 10 micrometers is an ion-conducting solid electrolyte.

6. Method according to claim 1, wherein the inorganic solid electrolyte, which is produced inside and on the surface of the porous, non-conducting substrate web, is a lithium thiophosphate.

7. Method according to claim 6, wherein before attachment and impregnation of the inorganic solid electrolyte to and into the porous, non-conducting substrate web, an inorganic coating of at most 20 nm in thickness is produced by ALD or CVD method on the surfaces of the porous structure of the substrate web.

8. Method according to claim 1, wherein in the cathode layer, an inorganic solid electrolyte is used, the electrolyte comprising lithium thiophosphate.

9. Method according to claim 8, wherein compositionally same inorganic solid electrolyte as in the electrolyte web is used in the cathode layer.

10. Method according to claim 1, wherein the cathode layer is processed by pressure and/or temperature after the deposition.

11. Method according to claim 1, wherein, an inorganic material layer with thickness of at most 10 nm is deposited by a coating method on the surface of the cathode-material particles.

12. Method according to claim 1, wherein the lithium-ion battery is further assembled in the method by using material layers which comprise an electrolyte web comprising inorganic solid electrolyte, the electrolyte web has been processed by pressure and/or temperature, an anode, a cathode, as well as potential protective layers, and wherein at least one material layer comprising lithium has been produced at least in part by pulsed laser deposition.

13. An electrochemical energy storage device utilising lithium, the device comprising:
a. an electrolyte web comprising 40-95 volume percent of inorganic solid electrolyte,
b. an anode material, and
c. a cathode material,
d. the electrolyte web is at most 200 micrometers thick and formed by processing a combination comprising inorganic solid electrolyte and porous, non-conducting substrate web by pressure and/or temperature so that the inorganic solid electrolyte impregnates into pores of the substrate web and densities to form ion-conducting pathways across the substrate web, and
e. the thickness of a lithium-metal anode layer is at most 50 micrometers.

14. Method according to claim 4, wherein the inorganic coating with thickness of at most 10 micrometers is an ion-conducting solid electrolyte comprising LiPON or LLZO.

15. Method according to claim 1, wherein the inorganic solid electrolyte, which is produced inside and on the surface of the porous, non-conducting substrate web, is a lithium thiophosphate comprising LPS or LGPS.

16. Method according to claim 1, wherein in the cathode layer, an inorganic solid electrolyte is used, the electrolyte comprising LPS or LGPS.
